(19) United States
(12) Patent Application Publication
(10) Pub. No.: US 2011/0227451 A1
(43) Pub. Date: Sep. 22, 2011

(54) RESONATOR BODY, RESONATOR DEVICE, AND ELECTRONIC DEVICE

(75) Inventor: Takashi YAMAZAKI, Shiojiri-shi (JP)

(73) Assignee: SEIKO EPSON CORPORATION, TOKYO (JP)

(21) Appl. No.: 13/043,823

(22) Filed: Mar. 9, 2011

(30) Foreign Application Priority Data
Mar. 18, 2010 (JP) 2010-062060
Dec. 28, 2010 (JP) 2010-292042

(51) Int. Cl. H01L 41/04; H01L 41/107

(52) U.S. Cl. 310/318; 310/325

(57) ABSTRACT

A resonator body of a resonator device includes a base portion, two resonating arms that are extended from the base portion in a Y axis direction and arranged in parallel to an X axis direction that is orthogonal to the Y axis direction, and excitation electrodes that are arranged on each of the resonating arms in a pair and excite the resonating arms by applying an electric current, wherein a plurality of holes that partially penetrates at least one side of a pair of excitation electrodes in a thickness direction is formed so that the vibration characteristic of the resonating arm is adjusted.

### BACKGROUND

1. Technical Field

The present invention relates to a resonator body, a resonator device that includes the resonator body, and an electronic device that includes the resonator device.

2. Related Art

As the resonator body that is used for the resonator device, a tuning-fork type resonator body that includes a plurality of resonating arms has been known.

For example, a resonator body illustrated in JP-A-2002-280870 has a base portion, two resonating arms that are extended from the base portion so as to be parallel to each other, and a pair of excitation electrodes and a pair of side surface excitation electrodes that are arranged on each of the resonating arms. In the resonator body, the base portion and each of the resonating arms are constituted of crystal and an electric field is applied between the pair of excitation electrodes and the pair of side surface excitation electrodes so that each of the resonating arms is vibrated.

An oscillation signal according to the resonator body includes many signal components of a frequency of a desired fundamental wave and also includes signal components of a frequency of a harmonic wave other than the signal components of the frequency of the fundamental wave. When a ratio of CI (crystal impedance) values that is a CI value of the harmonic wave (higher order vibration mode) of resonator body divided by a CI value of the fundamental wave (base vibration mode) is small, the signal component of the harmonic wave that is a noise component is large and there is a concern that there is abnormality in the device.

Thus, in the resonator body disclosed in JP-A-2002-280870, the length of the excitation electrode is about half of the resonating arms so that the ratio of CI values is increased.

However, when the length of the excitation electrode is about half of the resonating arms in the resonator body, the CI value of the fundamental wave becomes large. Thus, in the resonator body disclosed in JP-A-2002-280870, there is a problem that the resonator body cannot be effectively driven.

### SUMMARY

An advantage of some aspects of the invention is that it provides a resonator body, a resonator device that includes the resonator body, and an electronic device that includes the resonator device which can mitigate an unnecessary vibration mode and can be effectively driven.

### Application Example 1

According to this application example of the invention, there is provided a resonator body including a base portion, a plurality of resonating arms that is extended from the base portion to a first direction and arranged in parallel to a second direction that is orthogonal to the first direction, and a pair of excitation electrodes that is arranged on each of the resonating arms and excites the resonating arms by applying an electric current, wherein a plurality of holes that partially penetrates the excitation electrode of at least one side of a pair of excitation electrodes in a thickness direction is formed.

According to this configuration, the resonator body increases the length of the excitation electrode in the first direction (the extension direction of the resonating arm) on the resonating arm while decreasing a density of an electric field that is contributed to the unnecessary vibration mode out of electric fields (electric fields that are applied to the resonating arm) that are generated between a pair of excitation electrodes so that the resonator body can adjust the vibration characteristic of the resonating arm.

Thus, the resonator body of the application example of the invention can mitigate the unnecessary vibration mode and can be effectively driven.

### Application Example 2

It is preferable that a plurality of holes is unevenly distributed and formed at the excitation electrode of at least one side of the excitation electrodes in the first direction.

According to this configuration, the ratio of the CI value of the harmonic wave (the higher order vibration mode) and the CI value of the fundamental wave (the base vibration mode) is changed and then the resonator body can adjust a vibration characteristic of the resonating arm.

### Application Example 3

In the resonator body according to the application example, it is preferable that a plurality of holes is unevenly distributed at the center portion of the resonating arm of the excitation electrode in the first direction.

According to this configuration, the resonator body can increase the ratio of the CI values (the CI value of the harmonic wave/the CI value of the fundamental wave) such that the CI value of the fundamental wave is decreased and the CI value of the harmonic wave is increased.

### Application Example 4

In the resonator body according to the application example it is preferable that a ratio of the area in which the holes of the excitation electrode take a share per a unit area is gradually decreased toward a front end side from the center portion of the resonating arm in the first direction.

According to this configuration, the resonator body smoothly and effectively performs the excitation of the resonating arm and increases the CI value of the harmonic wave so that the ratio of the CI values (the CI value of harmonic wave/the CI value of fundamental wave) can be increased.

### Application Example 5

In the resonator body according to the application example it is preferable that a ratio of the area in which the holes of the excitation electrode take a share per a unit area is gradually decreased toward a base end side from the center portion of the resonating arm in the first direction.

According to this configuration, the resonator body smoothly and effectively performs the excitation of the resonating arm and increases the CI value of the harmonic wave so that the ratio of the CI values (the CI value of harmonic wave/the CI value of fundamental wave) can be increased.

### Application Example 6

In the resonator body according to the application example it is preferable that when a length of the resonating arm in the first direction is L1 and a length of the excitation electrode in the same direction on the resonating arm is L2, a relation of 0.5<L2/L1<1 is satisfied.

According to this configuration, the resonator body decreases the CI value of the fundamental wave and can effectively perform the excitation of the resonating arm.

### Application Example 7

In the resonator body according to the application example it is preferable that each hole is a circular shape seen in a plan view.

According to this configuration, the resonator body can relatively simply adjust the resonating arm to a desired vibration characteristic.

### Application Example 8

In the resonator body according to the application example it is preferable that an average diameter of a plurality of the holes is 0.01 to 100 μm.

According to this configuration, the resonator body can relatively simply form a plurality of holes and can adjust the resonating arm to a desired vibration characteristic.

### Application Example 9

In the resonator body according to the application example it is preferable that each of the holes is a slit shape seen in a plan view.

According to this configuration, the resonator body can relatively simply adjust the resonating arm to a desired vibration characteristic.

### Application Example 10

In the resonator body according to the application example it is preferable that each hole having the slit shape is extended to the second direction.

According to this configuration, the resonator body can relatively simply adjust the resonating arm to a desired vibration characteristic.

### Application Example 11

In the resonator body according to the application example it is preferable that a width of a hole having the slit shape is 0.01 to 100 μm.

According to this configuration, the resonator body can relatively simply form a plurality of holes and can adjust the resonating arm to a desired vibration characteristic.

### Application Example 12

According to this application example of the invention, there is provided a resonator body including: a base portion, a plurality of resonating arms that is extended from the base portion to a first direction and arranged in parallel to a second direction that is orthogonal to the first direction, and a piezoelectric body element that is arranged on each of the resonating arms and expanding and contracting so as to vibrate the resonating arms by applying an electric current, wherein the piezoelectric body element has a first electrode layer and a second electrode layer and piezoelectric body layers that are positioned between the first electrode layer and the second electrode layer, wherein a plurality of holes that partially penetrates at least one layer of the first electrode layer, the piezoelectric body layer, and the second electrode layer in a thickness direction is formed.

According to this configuration, the resonator body increases the length of the piezoelectric body element in the first direction on the resonating arm while decreasing a density of an electric field that is contributed to the unnecessary vibration mode out of electric fields (electric fields that are applied to the piezoelectric body layer) that are generated between the first electrode layer and the second electrode layer so that the resonator body can adjust the vibration characteristic of the resonating arm.

Thus, the resonator body of the application example of the invention can mitigate the unnecessary vibration mode and can be effectively driven.

### Application Example 13

In the resonator body according to the application example it is preferable that the resonating arms are three or more, and the adjacent two resonating arms are flexurally vibrated by expanding and contracting of the piezoelectric body element in opposite directions to each other in a third direction that is orthogonal to the first direction and the second direction.

According to this configuration, the resonator body prevents the loss of the vibration and can flexurally vibrate three or more resonating arms in the third direction.

### Application Example 14

According to this application example of the invention, there is provided a resonator device including the above described resonator body and a package that accommodates the resonator body.

According to this configuration, the resonator device can be effectively driven by the resonator body that mitigates the unnecessary vibration mode.

### Application Example 15

According to this application example of the invention, there is provided a resonator device including the above described resonator body, a circuit portion that is electrically connected to the resonator body, and a package that accommodates the resonator body and the circuit portion.

According to this configuration, the resonator device includes the resonator body that mitigates the unnecessary vibration mode and the circuit portion so that an excellent oscillation characteristic can be included.

### Application Example 16

According to this application example of the invention, there is provided an electronic device including the above described resonator device.

According to this configuration, the electronic device mitigates the unnecessary vibration mode, can be effectively driven, and have high reliability.

### BRIEF DESCRIPTION OF THE DRAWINGS

The invention will be described with reference to the accompanying drawings, wherein like numbers reference like elements.

FIG. 1 is a cross section view illustrating the resonator device of a first embodiment according to the invention.

FIG. 2 is a top plan view illustrating a resonator body included in the resonator device illustrated in FIG. 1.

FIG. 3 is a cross section view taken along line A-A in FIG. 2.

FIG. 4A is a graph illustrating a relationship between a position of the resonating arm of the resonator body in an extension direction (Y-axis direction) shown in FIG. 2, and a displacement amount, and a distortion amount of a base vibration mode of the resonating arm.

FIG. 4B is a graph illustrating a relationship between the position of the resonating arm of the resonator body in a, extension direction (Y-axis direction) shown in FIG. 2, and the displacement amount, and the distortion amount of a higher order vibration mode of the resonating arm.

FIG. 5 is a graph illustrating a relationship between the position of the resonating arm of the resonator body in an extension direction (Y-axis direction) shown in FIG. 2 and a ratio of an area of which an excitation electrode takes a share per a unit area on the resonating arm.

FIG. 6 is a top plan view illustrating the resonator body that is included in the resonator device of a second embodiment according to the invention.

FIG. 7 is a side view illustrating the resonator body shown in FIG. 6.

FIG. 8 is a top plan view illustrating the resonator body that is included in the resonator device of a third embodiment according to the invention.

FIG. 9 is a side view illustrating the resonator body shown in FIG. 8.

FIG. 10 is a bottom plan view illustrating the resonator body that is included in the resonator device of a fourth embodiment according to the invention.

FIG. 11 is a cross section view taken along line A-A in FIG. 10.

FIG. 12 is a drawing illustrating the resonator body shown in FIG. 10, in which each of the second electrode layers that is included in the resonator body is not shown.

FIG. 13 is a drawing illustrating the resonator body shown in FIG. 10, in which each of the second electrode layer and each of the piezoelectric body layers that are included in the resonator body are not shown.

FIG. 14 is a perspective view illustrating an operation of the resonator body shown in FIG. 10.

FIG. 15 is a cross section view illustrating the resonator device of a fifth embodiment according to the invention.

FIG. 16 is a perspective view schematically illustrating an outer appearance of a cellular phone as an example of the electronic device.

FIG. 17 is a circuit block illustrating a circuit constitution of the cellular phone.

FIG. 18 is a perspective view schematically illustrating an outer appearance of a personal computer as an example of the electronic device.

### DESCRIPTION OF EXEMPLARY EMBODIMENTS

Hereinafter, a resonator body, a resonator device, and an electronic device according to the invention will be described based on embodiments illustrated in the attached drawings.

### First Embodiment

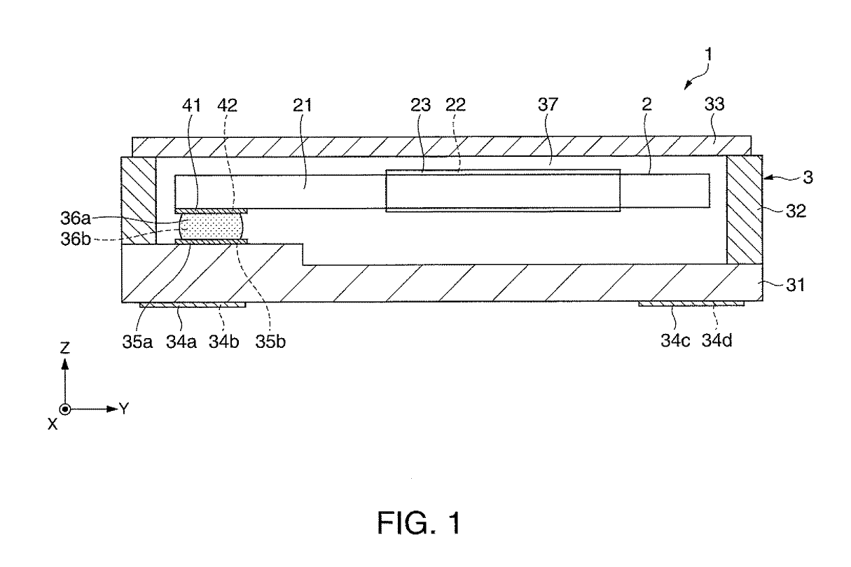

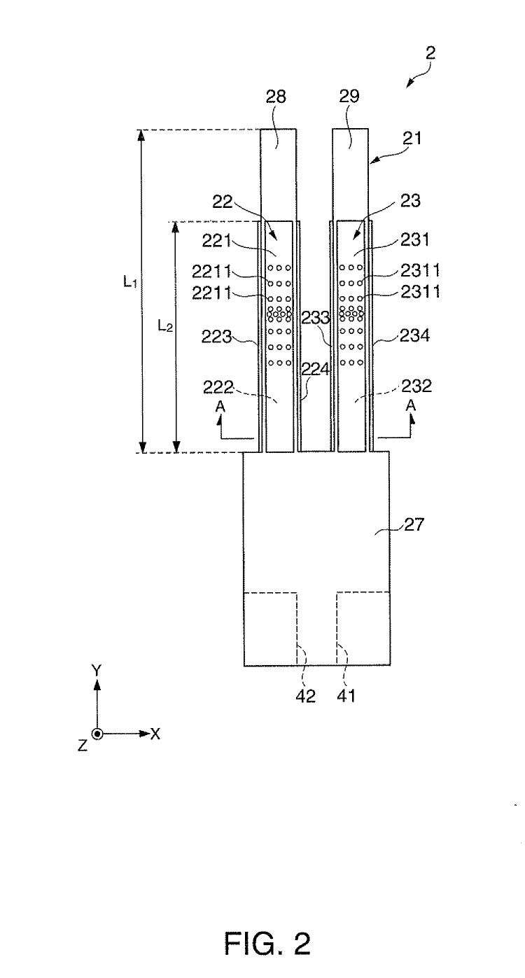

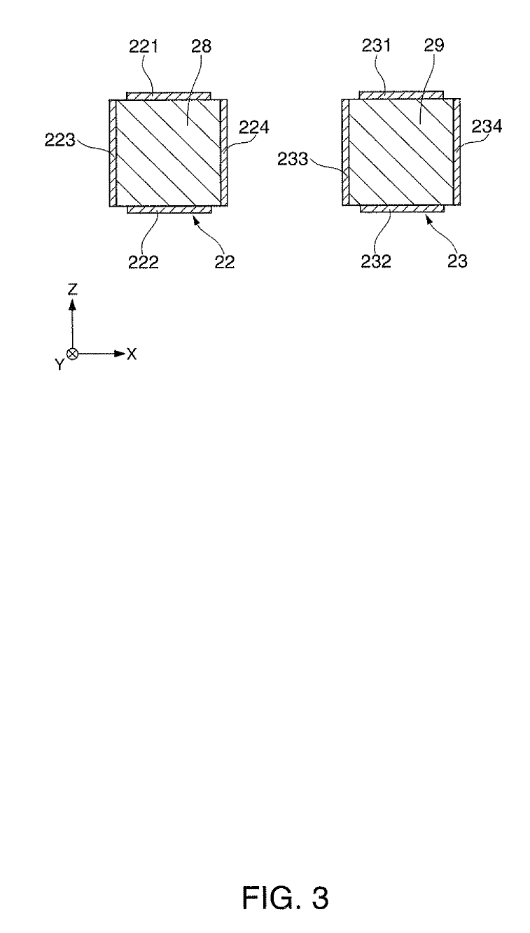

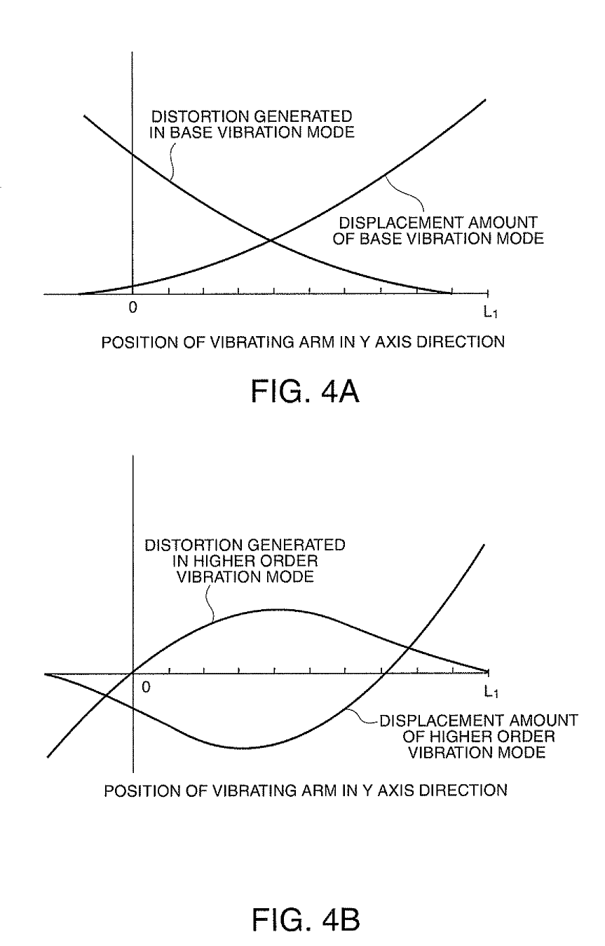

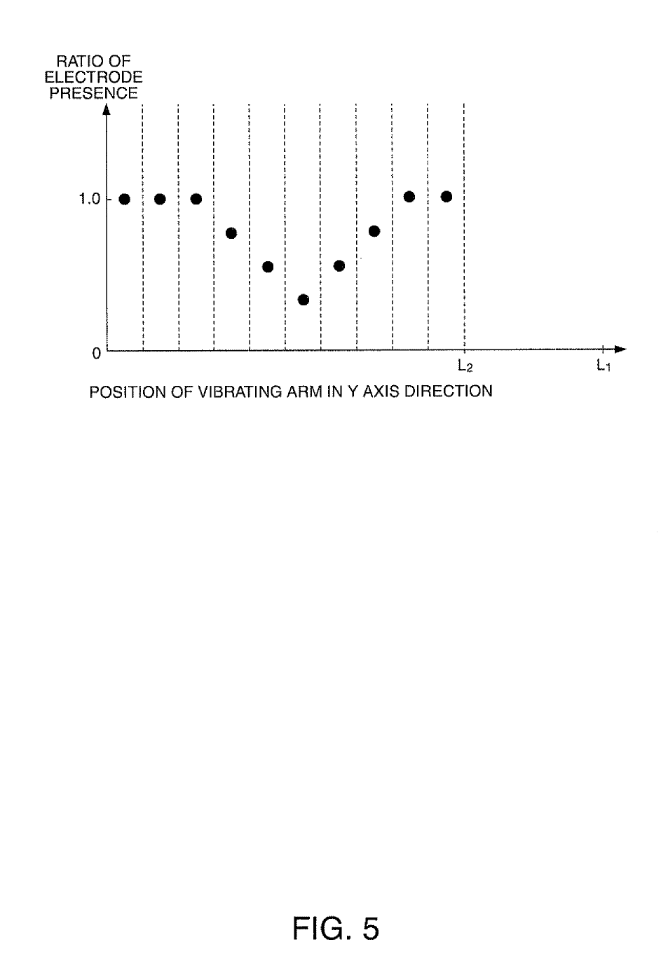

FIG. 1 is a cross section view illustrating the resonator device of a first embodiment according to the invention, FIG. 2 is a top plan view illustrating the resonator body included in the resonator device that is illustrated in FIG. 1, FIG. 3 is a cross section view taken along line A-A in FIG. 2, FIG. 4A is a graph illustrating a relationship between a position of the resonating arm of the resonator body in an extension direction (Y-axis direction) shown in FIG. 2, and a displacement amount, and a distortion amount of a base vibration mode of the resonating arm, FIG. 4B is a graph illustrating a relationship between a position of the resonating arm of the resonator body in an extension direction (Y-axis direction) shown in FIG. 2, and the displacement amount, and the distortion amount of a higher order vibration mode of the resonating arm and FIG. 5 is a graph illustrating a relationship between the position of the resonating arm of the resonator body in an extension direction (Y-axis direction) shown in FIG. 2 and a ratio of an area of which an excitation electrode takes a share per a unit area on the resonating arm.

In each of FIGS. 1 to 3, for the sake of convenience of description, the X-axis, the Y-axis and the Z-axis are illustrated as three axes orthogonal to each other. Hereinafter, a direction (the second direction) that is parallel to the X-axis is referred to as “X-axis direction”, a direction (the first direction) that is parallel to the Y-axis is referred to as “Y-axis direction”, and a direction (the third direction) that is parallel to the Z-axis is referred to as “Z-axis direction”. Also, in the description below, for the sake of convenience of description, an upper side in FIG. 1 is referred to as “upper”, a lower side is referred to as “lower”, a right side is referred to as “right” and a left side is referred to as “left”.

A resonator device 1 illustrated in FIG. 1 has a resonator body 2 and a package 3 in which the resonator body 2 is accommodated.

Hereinafter, each of the portions that are constituted of the resonator device 1 is described in detail in regular sequence.

### Resonator Body

First of all, description will be given regarding the resonator body 2.

The resonator body 2 is a tuning-fork type resonator body as illustrated in FIG. 2. The resonator body 2 has a vibrating substrate 21, and excitation electrode groups 22 and 23, and connection electrodes 41 and 42 provided on the vibrating substrate 21.

The vibrating substrate 21 has a base portion 27 and two (a pair) resonating arms 28 and 29.

The vibrating substrate 21 is constituted of a piezoelectric body.

For example, a crystal, lithium tantalite, lithium niobate, lithium borate, barium titanate or the like are used as examples of the piezoelectric body. Specifically, the crystal is preferred as the piezoelectric body that constitutes the vibrating substrate 21. When the vibrating substrate 21 is constituted of the crystal, the vibration characteristic of the vibrating substrate 21 can be excellent. Also, the vibrating substrate 21 can be formed with high precision dimension by etching.

In such a vibrating substrate 21, the base portion 27 has a tetragonal shape, seen in the plan view, constituted of a pair of sides that is parallel to the X-axis direction and a pair of sides that is parallel to the Y-axis direction. The shape of the base portion 27 seen in plan view is not limited to the above description.

Two resonating arms 28 and 29 are connected to one side of the base portion 27 that is parallel to the X-axis direction.

The resonating arms 28 and 29 are connected to both end portions of the base portion 27 in the X-axis direction.

Two resonating arms 28 and 29 are arranged and extended from the base portion 27 respectively so as to be parallel to each other. In other words, two resonating arms 28 and 29 are extended from the base portion 27 in the Y-axis direction respectively and arranged in parallel to the X-axis direction.

The resonating arms 28 and 29 have a longitudinal shape respectively, an end portion (a base end portion) of the base portion 27 is a fixed end and an end portion (a front end portion) that is opposite to the base portion 27 is a free end.

The resonating arms 28 and 29 are formed having the same width to each other. Accordingly, when the resonating arms 28 and 29 are vibrated in opposite directions (in reverse phase) to each other, loss of the vibration can be small.

Each of the resonating arms 28 and 29 has a constant width through an overall area in the longitudinal direction. If necessary, a mass portion (a hammer head) of which the cross section area is larger than that of the base end portion may be arranged at each of the front-end portions of the resonating arms 28 and 29. In this case, the resonator body 2 can be a more compact size and the vibration frequency of the resonating arms 28 and 29 can be further lowered.

The cross section of each of the resonating arms 28 and 29 is a quadrangular shape. The shape of the cross section of each of the resonating arms 28 and 29 is not limited to the quadrangular shape and for example, may be an H shape by forming a groove along the Y-axis direction at the upper and lower surface of each of the resonating arms 28 and 29.

As shown in FIG. 3, an excitation electrode group 22 is arranged on the resonating arm 28 and an excitation electrode group 23 is arranged on the resonating arm 29.

The excitation electrode group 22 has a function that performs a flexural vibration (excitation) of the resonating arm 28 by applying an electric current. The excitation electrode group 23 has a function that performs a flexural vibration (excitation) of the resonating arm 29 by applying an electric current.

As described above, the excitation electrode group 22 is constituted of an excitation electrode 221 that is arranged on the upper surface of the resonating arm 28, an excitation electrode 222 that is arranged on the lower surface of the resonating arm 28, an excitation electrode 223 that is arranged at a side surface of one side of the resonating arm 28 and an excitation electrode 224 that is arranged at a side surface of the other side of the resonating arm 28.

The excitation electrodes 221, 222, 223, and 224 are extended to near the front end side from near the base end side of the resonating arm 28 respectively. Width of each of the excitation electrodes 221, 222, 223, and 224 in the x-axis direction is constant through an overall area in the Y-axis direction.

Specifically, as shown in FIG. 2, a plurality of fine holes 2211 that penetrates the excitation electrode 221 in the thickness direction is formed. A plurality of fine holes (not shown) that penetrates the excitation electrode 222 in the thickness direction is also formed. Such a plurality of holes is formed at the excitation electrodes 221 and 222 respectively so that the vibration characteristic of the resonating arm 28 is adjusted. Adjustment of the vibration characteristic of the resonating arm 28 will be described below.

The same as above, the excitation electrode group 23 is constituted of an excitation electrode 231 that is arranged on the upper surface of the resonating arm 29, an excitation electrode 232 that is arranged on the lower surface of the resonating arm 29, an excitation electrode 233 that is arranged at a side surface of one side of the resonating arm 29, and an excitation electrode 234 that is arranged at a side surface of the other side of the resonating arm 29.

The excitation electrodes 231, 232, 233, and 234 are extended to near the front end side from near the base end side of the resonating arm 29 respectively. Width of each of the excitation electrodes 231, 232, 233, and 234 in the x-axis direction is constant through an overall area in the Y-axis direction.

Specifically, as shown in FIG. 2, a plurality of fine holes 2311 that penetrates the excitation electrode 231 in the thickness direction is formed. A plurality of fine holes (not shown) that penetrates the excitation electrode 232 in the thickness direction is also formed. Such a plurality of holes is formed at the excitation electrodes 231 and 232 respectively so that the vibration characteristic of the resonating arm 29 is adjusted.

The excitation electrodes 221, 222, 223, and 224 are electrically connected to a connection electrode 41 through a wiring (not shown). The excitation electrodes 223, 224, 231, and 232 are electrically connected to a connection electrode 42 through a wiring (not shown).

In the resonator body 2 as described above, when a voltage is applied between the connection electrode 41 and the connection electrode 42, the excitation electrodes 221, 222, 233, and 234 and the excitation electrodes 223, 224, 231, and 232 become reverse polarity so that the voltage of which a direction includes a component of the X-axis direction is applied to the resonating arms 28 and 29 respectively. Thus, each of the resonating arms 28 and 29 can perform flexural vibration with a constant frequency (a resonance frequency) due to a reverse piezoelectric effect of the piezoelectric body. At this time, the resonating arms 28 and 29 perform the flexural vibration in the opposite direction to each other.

When the resonating arms 28 and 29 are flexurally vibrated, the voltage having a constant frequency is generated by the piezoelectric effect of the piezoelectric body between the connection electrodes 41 and 42. The resonator body 2 can generate an electric signal that is vibrated in the resonance frequency using these properties.

The excitation electrode group 22 and 23, the connection electrodes 41 and 42, and the wiring (not shown) can be formed by a metal material that is excellent in conductivity such as aluminum, aluminum alloy, silver, silver alloy, chromium, chromium alloy, gold, gold chromium laminated film, respectively.

As a forming method of these electrodes, a physical film forming method such as a sputtering method or a vacuum vapor deposition method, a chemical vapor deposition method such as CVD, and various coating methods such as an ink jet method can be used.

Description will be given below regarding the adjustment of the vibration characteristic of the resonating arm 28. The adjustment of the vibration characteristic of the resonating arm 28 is described representatively below, however, the adjustment of the vibration characteristic of the resonating arm 29 is also similar to the description of the resonating arm 28.

As described above, a plurality of fine holes 2211 that penetrates the excitation electrode 221 in the thickness direction is formed. A plurality of fine holes (not shown) that penetrates the excitation electrode 222 in the thickness direction is also formed the same as the above description.

Specifically, a plurality of fine holes 2211 that penetrates partially the excitation electrode 221 in the thickness direction is formed. A plurality of fine holes (not shown) that penetrates partially the excitation electrode 222 in the thickness direction is formed so as to correspond to a plurality of holes 2211 (similar to a plurality of holes 2211).

Thus, the length of each of the excitation electrodes 221, 222, 223, and 224 in the Y-axis direction is long on the resonating arm 28, while density of an electric field that contributes to the unnecessary vibration mode is small, of which electric fields (electric fields that are applied to the resonating arm 28) are generated between the excitation electrode 221 and the excitation electrodes 223 and 224, and between the excitation electrode 222 and the excitation electrodes 223 and 224 so that the vibration characteristic of the resonating arm 28 can be adjusted.

Accordingly, the resonator body 2 can mitigate the unnecessary vibration mode and can be effectively driven.

In the embodiment, a plurality of holes such as a plurality of holes 2211 is not formed at the excitation electrodes 223 and 224. In other words, the excitation electrodes 223 and 224 are not patterned at the inner side of the contour and constitute dense layers. Thus, the resonator body 2 can be easily manufactured.

Hereinafter, the relationship between a plurality of holes that is formed at the excitation electrodes 221 and 222 and the vibration characteristic of the resonating arm 28 will be described in detail. Also, the excitation electrode 221 is described representatively below, however, the excitation electrode 222 is similar to the description of the excitation electrode 221.

As described in detail, the resonating arm 28 of the resonator body 2 constituted as the above is excited with the frequency of a desired base vibration mode (fundamental wave), however, it may also be excited even with the frequency of the higher order vibration mode that differs from the base vibration mode, in addition to than the base vibration mode.

As shown in FIG. 4A, the displacement amount (the displacement amount of the neutral line) of the base vibration mode of the resonating arm 28 increases toward the front end side from the base end side of the resonating arm 28. Also, the distortion that is generated due to the displacement of the base vibration mode of the resonating arm 28 decreases toward the front-end side from the base end side of the resonating arm 28. In FIG. 4, the vertical axis illustrates the displacement amount of the resonating arm, a relative value of the distortion, and an electric charge.

Meanwhile, as shown in FIG. 4B, the displacement amount (the displacement amount of the neutral line) of the higher order vibration mode of the resonating arm 28 increases toward the front end side from the base end side of the resonating arm 28 to near the center portion and then decreases to near the front end side and increases after that. Also, the distortion that is generated due to the displacement of the higher order vibration mode of the resonating arm 28 increases toward the front end side from the base end side of the resonating arm 28 to near the center portion and then decreases.

Accordingly, the excitation of the base vibration mode is not so large at the center portion of the resonating arm 28 in the Y-axis direction, however, the excitation of the higher order vibration mode is large. The excitation of the higher order vibration mode is larger at the center portion than the end portion of the resonating arm 28 in the Y-axis direction.

A plurality of holes 2211 is unevenly distributed (partially formed) at halfway between the excitation electrode 221 of the resonating arm 28 in the extension direction. More specifically, a plurality of holes 2211 is unevenly distributed (partially formed) at a portion that corresponds to the center portion of the excitation electrode 221 in the extension direction of the resonating arm 28 (the Y-axis direction).

A plurality of holes 2211 is unevenly distributed at halfway between the excitation electrode 221 of the resonating arm 28 of the extension direction so that the ratio of a CI value of the harmonic wave (the higher order vibration mode) and a CI value of the fundamental wave is changed and then the vibration characteristic of the resonating arm 28 can be adjusted.

Specifically, a plurality of holes 2211 is unevenly distributed at a portion that corresponds to the center portion of the excitation electrode 221 in the extension direction of the resonating arm 28 (the Y-axis direction), the excitation of the higher order vibration mode of the resonating arm 28 is widely suppressed so that the CI value of the higher order vibration mode of the resonator body 2 can be increased even though the length L2 of the excitation electrode 221 in the Y-axis direction is long. In other words, the CI value of the fundamental wave is decreased and the CI value of the harmonic wave is increased so that the ratio of the CI values (the CI value of the harmonic wave/the CI value of the fundamental wave) can be increased.

When the length of the resonating arm 28 in the extension direction (the Y-axis direction) is L1 and the length of the excitation electrode 221 in the same direction on the resonating arm 28 is L2, the relation of 0.5<L2/L1<1 is satisfied. Accordingly, the CI value of the fundamental wave is decreased and the excitation of the resonating arm 28 can be effectively performed. Specifically, from such a viewpoint, the lengths L1 and L2 preferably satisfy the relation of 0.6<L2/L1<0.9 and further preferably satisfy the relation of 0.7<L2/L1<0.8.

If L2/L1 is less than the lower limit, the CI value of the fundamental wave is difficult to decrease sufficiently by the shape, the width, and the length of the resonating arm 28 or the like. Meanwhile, if L2/L1 is more than the upper limit, the CI value of the harmonic wave is difficult to increase by the shape, the width, and the length of the resonating arm 28 or the like.

The ratio (referred to as “the ratio of the hole presence” below) of the area in which the holes 2211 of the excitation electrode 221 that takes a share per a unit area is gradually decreased toward the front end side and the base end side from the center portion of the resonating arm 28 in the extension direction (the Y-axis direction). In other words, as shown in FIG. 5, the ratio (referred to as “the ratio of the electrode presence” below) of the area in which the electrodes take a share in each area that divides the excitation electrode 221 per a unit length in the Y-axis direction is gradually increased toward the front end side and the base end side from the center portion of the resonating arm 28 in the extension direction (the Y-axis direction). Accordingly, the excitation of the resonating arm 28 is smoothly and effectively performed and the CI value of the harmonic wave is increased so that the ratio of the CI values (the CI value of harmonic wave/the CI value of fundamental wave) can be increased.

If the ratio of the hole presence is increased and decreased according to the size of the distortion that is generated in the higher order vibration mode shown in FIG. 4B described above, the excitation of the higher order vibration mode can be further reliably decreased.

If the ratio of the hole presence is increased and decreased according to the difference between the size of the distortion that is generated in the higher order vibration mode shown in FIG. 4B and the size of the distortion that is generated in the base vibration mode shown in FIG. 4A, the excitation of the base vibration mode is increased and the excitation of the higher order vibration mode can be effectively decreased.

Each of the holes 2211 has a circular shape seen in the plan view. Thus, the resonating arm 28 can be relatively easily adjusted to a desired vibration characteristic. Also, each of the holes 2211 may be a substantially circular shape that is near a circular shape.

In the embodiment, a plurality of the holes 2211 is formed so as to have the same shape and area to each other seen in the plan view. Thus, the distance among the holes 2211 is changed according to the position in the Y-axis direction so that the ratio of the hole presence (the ratio of the electrode presence) is realized as described above.

A plurality of the holes 2211 may also be formed so as to have different shape and area to each other seen in the plan view. In this case, even though the distance among the holes 2211 is constant, the shape and the area of each of the holes 2211 seen in the plan view are changed according to the position in the Y-axis direction so that the ratio of the hole presence (the ratio of the electrode presence) can be realized as described above.

An average diameter of a plurality of the holes 2211 is preferably 0.01 to 100 μm and further preferably 0.1 to 10 μm. Thus, the formation of a plurality of the holes 2211 is relatively easily performed and the resonating arm 28 can be adjusted to the desired vibration characteristic.

Meanwhile, if the average diameter is less than the lower limit, the formation of a plurality of the holes 2211 may be difficult depending on constituent material and thickness of the excitation electrode 221 or the like. Meanwhile, if the average diameter is more than the upper limit, the share of the area of the holes 2211 in the desired region is difficult to increase. Negative influence may be exerted to the vibration characteristic of the resonating arm 28 by the range or the position in which the excitation electrode 221 is formed.

When the excitation electrode 221 is seen in the plan view, the ratio (the share of the area) of the area in which the plurality of holes 2211 takes a share with respect to the entire excitation electrode 221 is determined according to the obtained vibration characteristic of the resonating arm 28. The ratio is preferably 0.1 to 0.5 and further preferably 0.1 to 0.4. In other words, when the excitation electrode 221 is seen in the plan view, the ratio of the area in which the electrodes take a share within the region that is surrounded by the contour of the excitation electrode 221 is preferably 0.5 to 0.9 and more preferably 0.6 to 0.9 respectively. Thus, the continuity failure such as electric short circuiting of the excitation electrode 221, which is easily generated in the case that the ratio of the area which the electrodes take a share becomes small can be prevented and the resonating arm 28 can be adjusted to the desired vibration characteristic.

### Package

Next, description will be given regarding the package 3 that receives and fixes the resonator body 2.

As shown in FIG. 1, the package 3 has a plate shaped base substrate 31, a frame shaped frame member 32, and a plate shaped lid member 33. The base substrate 31, the frame member 32, and the lid member 33 are laminated in this order from the lower side to the upper side. The base substrate 31 and the frame member 32 are formed from a ceramic material as described below, fired integrally to each other and then connected together. The frame member 32 and the lid member 33 are connected to each other by an adhesive or brazing filler material. Thus, the package 3 accommodates the resonator body 2 in an inner space 37 partitioned by the base substrate 31, the frame member 32, and the lid member 33.

As the constituent material of the base substrate 31, it is preferable to have insulation property (non-conductivity), and for example, all types of glass, all types of ceramic material such as oxide ceramics, nitride ceramics, or carbide ceramics, and all types of resin material such as polyimide can be used.

As the constituent material of the frame member 32 and the lid member 33, for example, the same constituent material as the base substrate 31, all types of metal material such as Al or Cu, all types of glass, or the like can be used. Specifically, as the constituent material of the lid member 33, if a material that has a light transmittance such as glass material is used, when a metal coating portion (not shown) is formed at the resonator body 2 beforehand, even though the resonator body 2 is accommodated in the package 3, the laser irradiates the metal coating portion through the lid member 33, the metal coating portion is removed, and then the mass of the resonator body 2 is decreased (by mass decreasing method) so that the frequency adjustment of the resonator body 2 can be performed.

A pair of mount electrodes 35a and 35b is formed on the upper surface of the base substrate 31 so as to expose to the inner space 37. Conductive adhesives 36a and 36b such as epoxy, polyimide, and silicon including conductive particles are coated (covered) on the mount electrodes 35a and 35b respectively. The resonator body 2 is loaded on the conductive adhesives 36a and 36b. Thus, the resonator body 2 (the base portion 27) is reliably fixed to the mount electrodes 35a and 35b (the base substrate 31).

The fixing is performed with the resonator body 2 being loaded on the conductive adhesives 36a and 36b so that the conductive adhesive 36a is contacted to the connection electrode 42 of the resonator body 2 and the conductive adhesive 36b is contacted to the connection electrode 41 of the resonator body 2. Thus, the resonator body 2 is fixed to the base substrate 31 through the conductive adhesives 36a and 36b. The connection electrode 42 and the mount electrode 35a are electrically connected through the conductive adhesive 36a and the connection electrode 41 and the mount electrode 35b are electrically connected through the conductive adhesive 36b.

Four outer terminals 34a, 34b, 34c, and 34d are arranged at the lower surface of the base substrate 31.

The outer terminals 34a and 34b out of these four outer terminals 34a to 34d are hot terminals that are electrically connected to the mount electrodes 35a and 35b through a conductive post (not shown) that is arranged at the through hole that is formed in the base substrate 31 respectively. The other two outer terminals 34c and 34d are dummy terminals for increasing the connection strength and uniformizing the distance between the package 3 and the mounting substrate respectively when the package 3 is mounted on the mounting substrate.

As described above, the mount electrodes 35a and 35b and the outer terminals 34a to 34d can be formed for example, with gold coating at the foundation layer of tungsten and nickel coating respectively.

The mount electrodes 35a and 35b and the connection electrodes 41 and 42 may be electrically connected through a metal wire (bonding wire) formed, for example by a wire bonding technique. In this case, the resonator body 2 can be fixed to the base substrate 31 through an adhesive that does not have conductivity, instead of the conductive adhesives 36a and 36b.

According to the first embodiment as described above, a plurality of fine holes that penetrates the excitation electrodes 221 and 222 in the thickness direction at halfway between the longitudinal direction (Y-axis direction) is formed. Thus, the length of each of the excitation electrodes 221, 222, 223, and 224 in the Y-axis direction (the extension direction of the resonating arm 28) on the resonating arm 28 is long; and the density of the electric field that is contributed to the unnecessary voltage mode is small out of the electric fields (the electric field that is applied to the resonating arm 28) that is generated between the excitation electrode 221 and the excitation electrodes 223 and 224, and between the excitation electrode 222 and the excitation electrodes 223 and 224 respectively so that the vibration characteristic of the resonating arm 28 can be adjusted.

Accordingly, the resonator body 2 mitigates the unnecessary vibration mode and can be effectively driven.

### Second Embodiment

Next, the second embodiment of the resonator device according to the invention will be described.

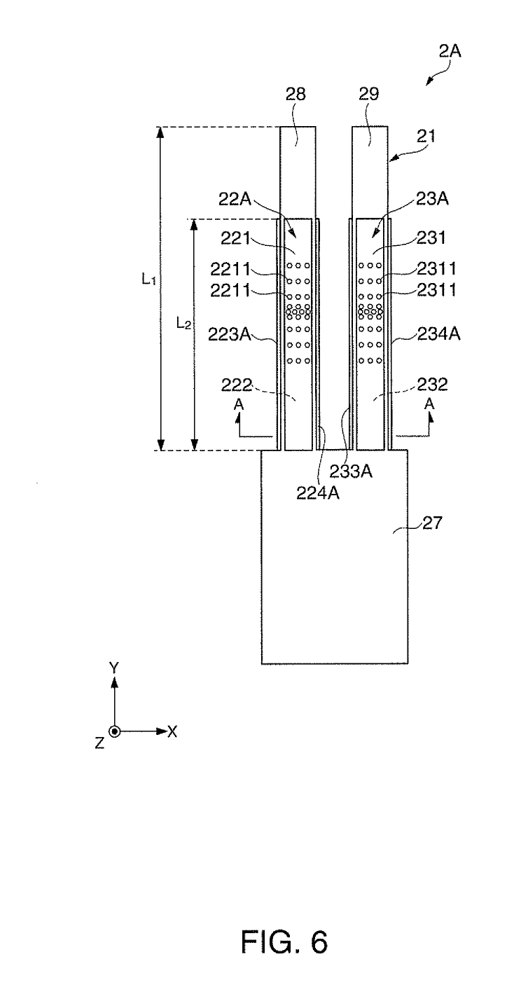

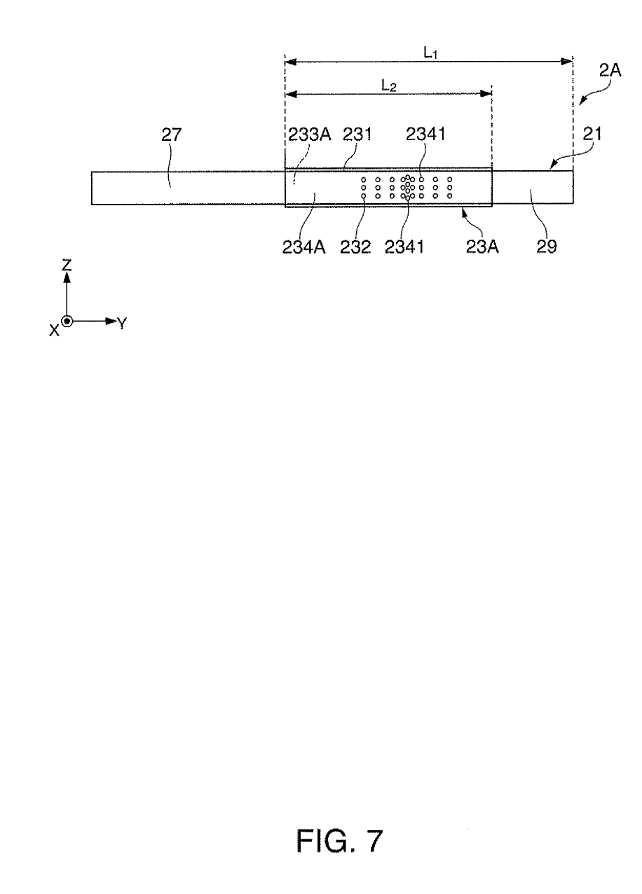

FIG. 6 is a top plan view illustrating the resonator body that is included in the resonator device of a second embodiment according to the invention and FIG. 7 is a side view illustrating the resonator body shown in FIG. 6.

Hereinafter, description will be given regarding the resonator device of the second embodiment focused on differences from the above described embodiment and the same articles thereof will not be described repeatedly.

The resonator device of the second embodiment is substantially the same as that of the first embodiment except that a plurality of fine holes is also formed at the excitation electrode that is arranged on each side surface of each resonating arm. Also, in FIGS. 6 and 7, the constituent elements similar to those of the above described embodiment are given similar reference numbers.

As shown in FIG. 6, a resonator body 2A of the resonator device of the embodiment has excitation electrode groups 22A and 23A that are arranged on the vibrating substrate 21.

The excitation electrode group 22A is arranged on the resonating arm 28 and the excitation electrode group 23A is arranged on the resonating arm 29.

The excitation electrode group 22A is constituted of the excitation electrode 221 that is arranged on the upper surface of the above described resonating arm 28, the excitation electrode 222 that is arranged on the lower surface of the resonating arm 28, an excitation electrode 223A that is arranged at the side surface of one side of the resonating arm 28 and an excitation electrode 224A that is arranged at the side surface of the other side of the resonating arm 28.

Also, the excitation electrode group 23A is constituted of the excitation electrode 231 that is arranged on the upper surface of the above described resonating arm 29, the excitation electrode 232 that is arranged on the lower surface of the resonating arm 29, an excitation electrode 233A that is arranged at the side surface of one side of the resonating arm 29, and an excitation electrode 234A that is arranged at the side surface of the other side of the resonating arm 29.

Hereinafter, description will be given regarding the excitation electrode group 23A. Regarding the excitation electrode group 22A, the constitution thereof is similar to that of the excitation electrode group 22 so that the description thereof is omitted.

As shown in FIG. 7, a plurality of fine holes 2341 that penetrates the excitation electrode 234A in the thickness direction is formed. Also, even though it is not shown, a plurality of fine holes that penetrates the excitation electrode 233A in the thickness direction is also formed.

Also, as shown in FIG. 6, a plurality of fine holes 2311 that penetrates the excitation electrode 231 in the thickness direction is formed, the same as the above described first embodiment. Also, even though not shown, a plurality of fine holes that penetrates the excitation electrode 232 in the thickness direction is also formed.

A plurality of holes is formed on the excitation electrodes 231, 232, 233A, and 234A respectively so that the vibration characteristic of the resonating arm 29 is adjusted.

In the embodiment, the above described plurality of holes is formed on both of a pair of the excitation electrodes (the excitation electrode 231 and the excitation electrodes 233A and 234A, and the excitation electrode 232 and the excitation electrode 233A and 234A) that have different polarities, so that the number or area of a plurality of holes per one excitation electrode can be further decreased compared to the case that a plurality of holes is formed on only either one excitation electrode of a pair of excitation electrodes. Thus, the continuity failure such as electric short circuiting of each of the excitation electrodes 231, 232, 233A, and 234A, can be prevented and the adjustment of the vibration characteristic of the resonating arm 29 can be performed. Also, it is preferable that the holes of one side of the excitation electrode (the excitation electrodes 231 and 232) and the holes of the other side of the excitation electrode (the excitation electrodes 233A and 234A) are not overlapped as much as possible in the Y-axis direction such that the effect becomes more remarkable.

According to the above described second embodiment, effect of the same as that of the first embodiment can be present.

### Third Embodiment

Next, a third embodiment of the resonator device according to the invention will be described.

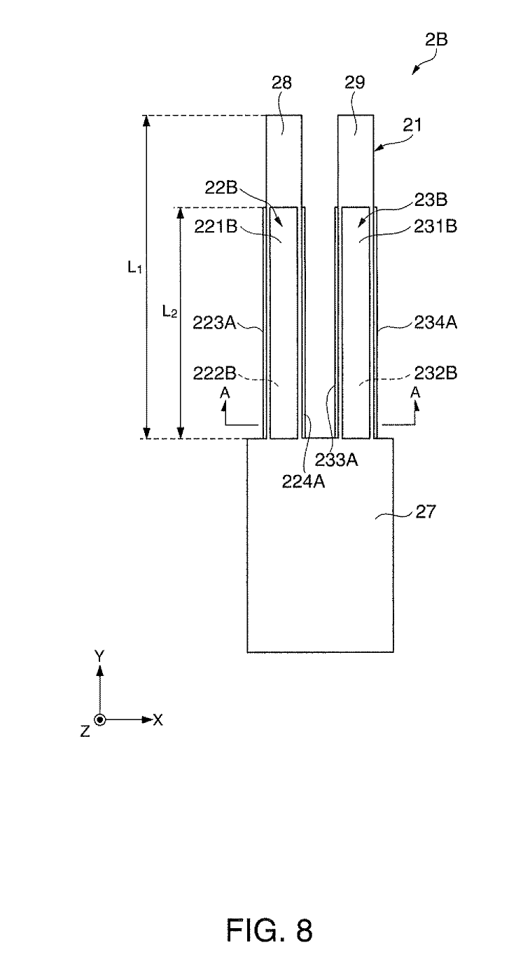

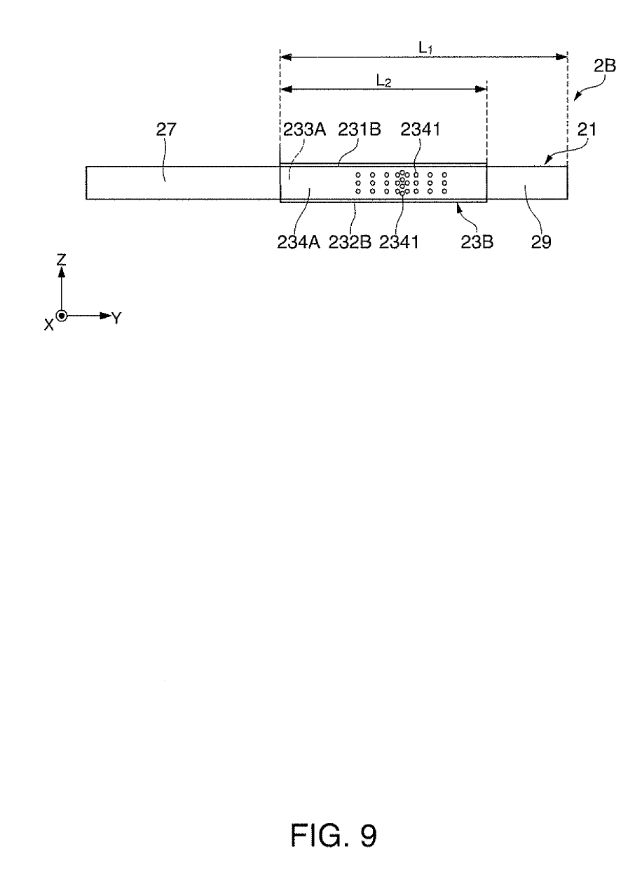

FIG. 8 is a top plan view illustrating the resonator body that is included in the resonator device of a third embodiment according to the invention and FIG. 9 is a side view illustrating the resonator body shown in FIG. 8.

Hereinafter, description will be given regarding the resonator device of the third embodiment focused on differences from the above described embodiments and the same articles thereof will not be described repeatedly.

The resonator device of the third embodiment is substantially the same as that of the first embodiment except that the formation of a plurality of holes is omitted at the excitation electrode that is arranged on the upper surface and the lower surface of each of the resonating arms, and a plurality of fine holes is also formed at the excitation electrode that is arranged on each side surface of each of the resonating arms. In other words, the resonator device of the third embodiment is substantially the same as that of the second embodiment except that the formation of a plurality of holes is omitted at the excitation electrode that is arranged on the upper surface and the lower surface of each of the resonating arms. Also, in FIGS. 8 and 9, the constituent elements similar to those of the above described embodiments are given similar reference numbers.

As shown in FIG. 8, a resonator body 2B of the resonator device of the embodiment has excitation electrode groups 22B and 23B that are arranged on the vibrating substrate 21.

The excitation electrode group 22B is arranged on the resonating arm 28 and the excitation electrode group 23B is arranged on the resonating arm 29.

The excitation electrode group 22B is constituted of an excitation electrode 221B that is arranged on the upper surface of the above described resonating arm 28, an excitation electrode 222B that is arranged on the lower surface of the resonating arm 28, an excitation electrode 223A that is arranged at the side surface of one side of the resonating arm 28, and an excitation electrode 224A that is arranged on the side surface of the other side of the resonating arm 28.

Also, the excitation electrode group 23B is constituted of an excitation electrode 231B that is arranged on the upper surface of the above described resonating arm 29, an excitation electrode 232B that is arranged on the lower surface of the resonating arm 29, an excitation electrode 233A that is arranged at the side surface of one side of the resonating arm 29, and an excitation electrode 234A that is arranged at the side surface of the other side of the resonating arm 29.

Hereinafter, description will be given regarding the excitation electrode group 23B. Regarding the excitation electrode group 22B, the constitution thereof is similar to that of the excitation electrode group 23B so that the description thereof is omitted.

As shown in FIG. 9, a plurality of fine holes 2341 that penetrates the excitation electrode 234A in the thickness direction is formed, the same as that of the above described second embodiment. Also, even though it is not shown, a plurality of fine holes that penetrates the excitation electrode 233A in the thickness direction is also formed the same as the above description.

Also, as shown in FIG. 8, a plurality of holes similar to the above described plurality of holes 2341 is not formed at the excitation electrodes 221 and 222. In other words, the excitation electrodes 221 and 222 are constituted such that the inner side of the contour is not patterned but constituted as dense layers.

A plurality of holes is formed on the excitation electrodes 233A and 234A respectively so that the vibration characteristic of the resonating arm 29 is adjusted.

In the embodiment, the ratio of the holes presence of the excitation electrodes 233A and 234A is preferable as the same as that of the excitation electrodes 221 and 222 of the above described first embodiment.

According to the above described third embodiment, the same effect as that of the first embodiment can be present.

### Fourth Embodiment

Next, a fourth embodiment of the resonator device according to the invention will be described.

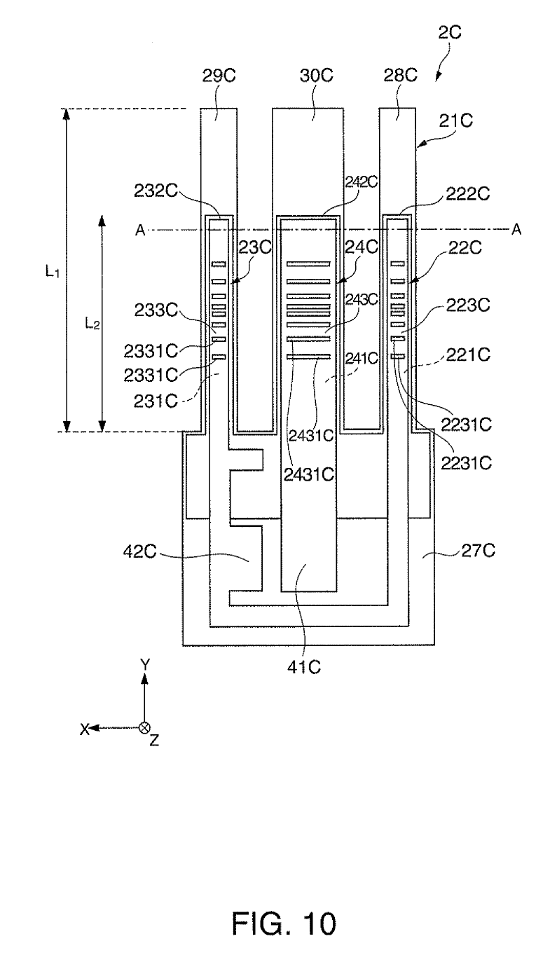

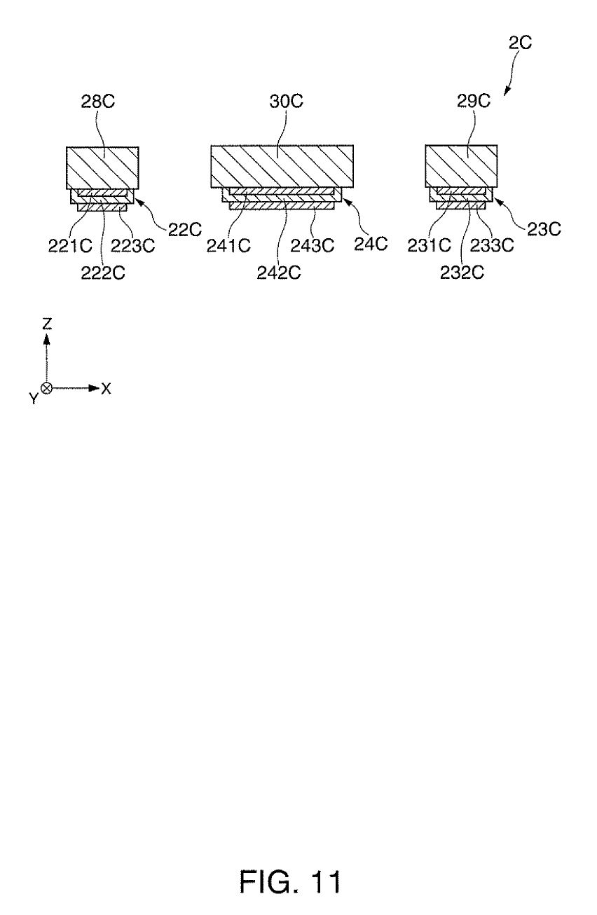

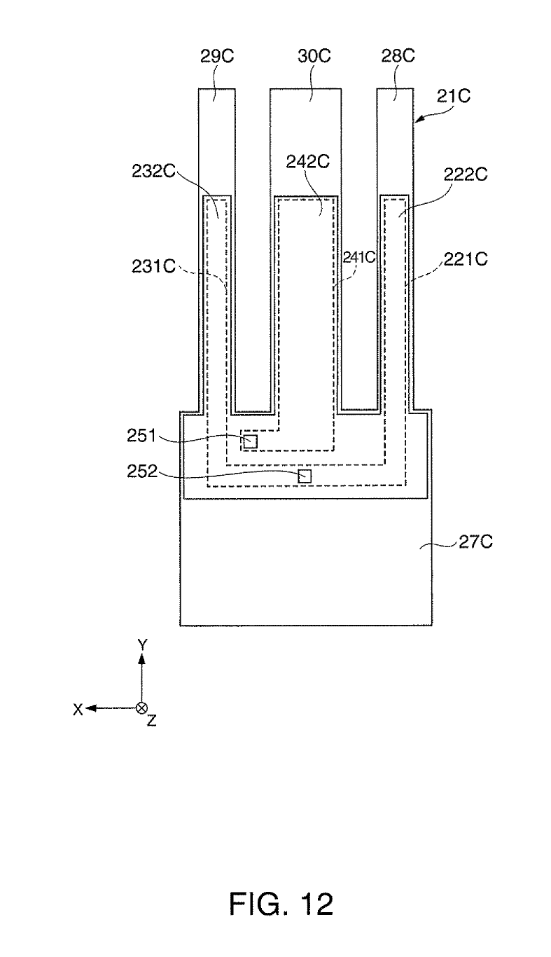

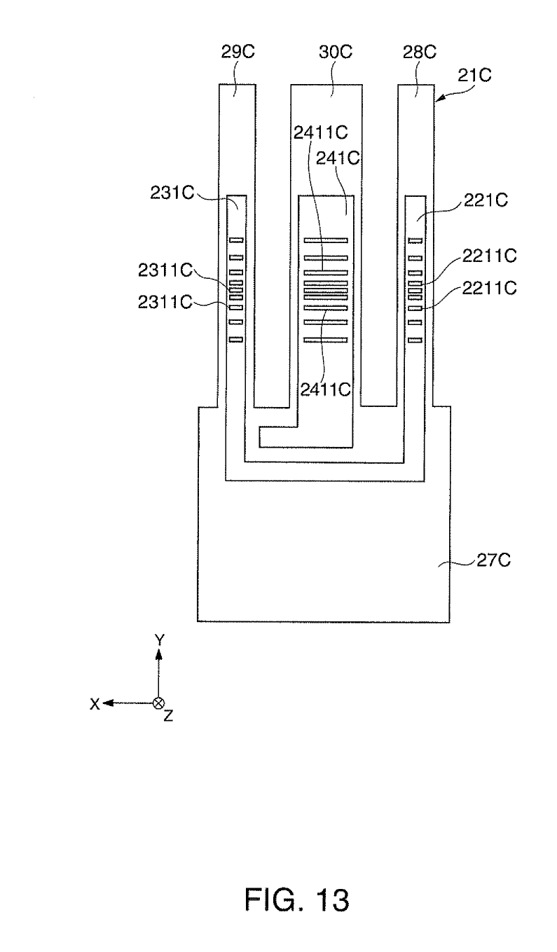

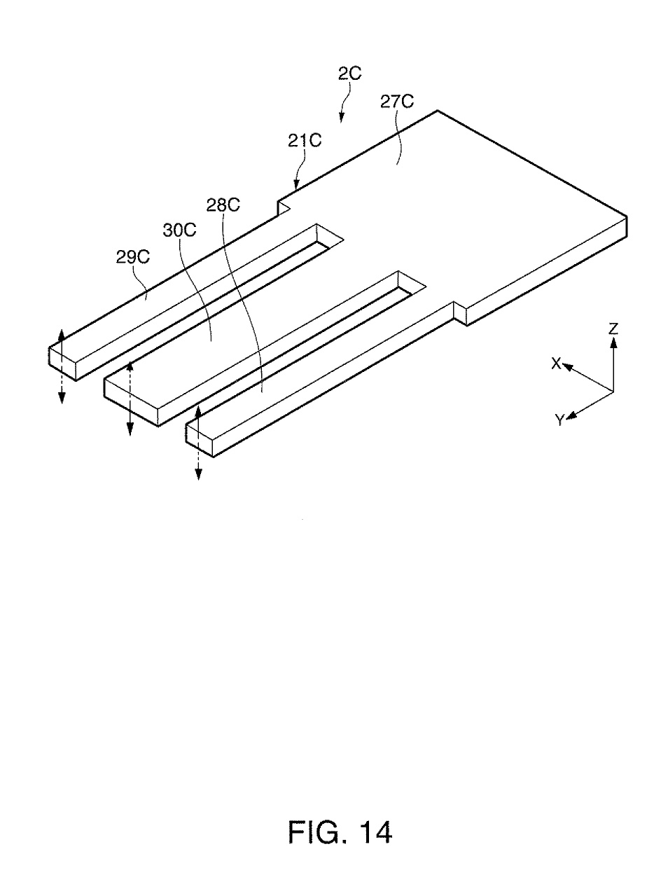

FIG. 10 is a bottom plan view illustrating the resonator body that is included in the resonator device of a fourth embodiment according to the invention, FIG. 11 is a cross section view taken along line A-A in FIG. 10, FIG. 12 is a drawing illustrating the resonator body shown in FIG. 10 in which each of the second electrode layers that is included in the resonator body is not shown, FIG. 13 is a drawing illustrating the resonator body shown in FIG. 10 in which each of the second electrode layer and each of piezoelectric body layers that are included in the resonator body is not shown, and FIG. 14 is a perspective view illustrating an operation of the resonator body shown in FIG. 10.

Hereinafter, description will be given regarding the resonator device of the fourth embodiment focused on differences from the above described embodiments and the same articles thereof will not be described repeatedly.

The fourth embodiment is substantially the same as the first embodiment except that the number of resonating arms is different and a plurality of fine holes is formed at the first electrode layer and the second electrode layer of the piezoelectric body element in a constitution in which each of the resonating arms is vibrated by the piezoelectric body element.

As shown in FIG. 10, a resonator body 2C of the resonator device of the embodiment is a three-pronged tuning-fork type resonator body. The resonator body 2C has a vibrating substrate 21C and piezoelectric body elements 22C, 23C, and 24C that are arranged on the vibrating substrate 21C.

The vibrating substrate 21C has a base portion 27C and three resonating arms 28C, 29C, and 30C.

A constituent material of the vibrating substrate 21C is not specifically limited so long as it exerts a desired vibration characteristic and can use all types of the piezoelectric bodies and all types of the non-piezoelectric bodies.

For example, crystal, lithium tantalite, lithium niobate, lithium borate, barium titanate, or the like are given as examples of the piezoelectric body. Specifically, crystal is preferred as the piezoelectric body that constitutes the vibrating substrate 21C. When the vibrating substrate 21C is constituted of crystal, the vibration characteristic of the vibrating substrate 21C can be excellent. Also, the vibrating substrate 21C can be formed with high precision dimension by etching.

As non-piezoelectric bodies, for example, silicon, quartz, or the like can be used. Specifically, as the non-piezoelectric bodies that constitute the vibrating substrate 21C, silicon is preferable. When the vibrating substrate 21C is constituted of silicon, the vibration characteristic of the vibrating substrate 21C may be excellent. Also, the vibrating substrate 21C can be formed with high precision dimension by etching.

In the vibrating substrate 21C, the base portion 27C has a tetragonal shape seen in the plan view constituted of a pair of sides that is parallel to the X-axis direction and a pair of sides that is parallel to the Y-axis direction. The shape of the base portion 27C seen in plan view is not limited to the above description.

Three resonating arms 28C, 29C, and 30C are connected to one side of the base portion 27C that is parallel to the X-axis direction.

The resonating arms 28C and 29C are connected to both end portions of the base portion 27C in the X-axis direction and the resonating arm 30C is connected to the center portion of the base portion 27 in X-axis direction.

Three resonating arms 28C, 29C, and 30C are extended from the base portion 27C in the Y-axis direction respectively and arranged in parallel in the X-axis direction.

The resonating arms 28C, 29C, and 30C have a long quadrangle shape respectively, an end portion (a base end portion) of the base portion 27C is a fixed end and an end portion (a front end portion) that is opposite to the base portion 27C is a free end.

The resonating arms 28C and 29C are formed so as to be the same width as each other. The resonating arms 30C is formed so as to be the width thereof being two times of that of the resonating arms 28C and 29C. Accordingly, if the resonating arms 28C and 29C are flexurally vibrated in the Z-axis direction and the resonating arms 30C is flexurally vibrated in the opposite direction (in reverse phase) to the resonating arms 28C and 29C in the Z-axis direction, loss of the vibration can be small.

Each of the resonating arms 28C, 29C, and 30C has a constant width through an overall area in the longitudinal direction. If necessary, a mass portion (a hammer head) may be arranged, of which the cross section area is larger than that of the base end portion at each of the front end portions of the resonating arms 28C, 29C, and 30C. In this case, the resonator body 2C can be a more compact size and the flexural vibration frequency of the resonating arms 28C, 29C, and 30C can be further lowered.

As shown in FIG. 11, the piezoelectric body element 22C is arranged on the resonating arm 28C, the piezoelectric body element 23C is arranged on the resonating arm 29C and the piezoelectric body element 24C is arranged on the resonating arm 30C.

The piezoelectric body element 22C has a function that performs a flexural vibration of the resonating arm 28C in the z-axis direction by expanding and contracting by applying an electric current. The piezoelectric body element 23C has a function that performs a flexural vibration of the resonating arm 29C in the Z-axis direction by expanding and contracting by applying an electric current. Also the piezoelectric body element 24C has a function that performs a flexural vibration of the resonating arm 30C in the Z-axis direction by expanding and contracting by applying an electric current.

As shown in FIG. 11, the piezoelectric body element 22C is constituted such that a first electrode layer 221C, a piezoelectric body layer (piezoelectric thin film) 222C, and a second electrode layer 223C are laminated in this order on the resonating arm 28C.

As shown in FIG. 10, a plurality of fine holes 2231C that penetrates the second electrode layer 223C in the thickness direction is formed in a slit shape. As shown in FIG. 13, a plurality of fine holes 2211C that penetrates the first electrode layer 221C in the thickness direction is formed in a slit shape. Such a plurality of holes is formed at the first electrode layer 221C and the second electrode layer 223C so that the vibration characteristic of the resonating arm 28C is adjusted. Adjustment of the vibration characteristic of the resonating arm 28C will be described below.

In the piezoelectric body element 220, the piezoelectric body layer 222C is arranged between the first electrode layer 221C and the second electrode layer 223C, thus when a voltage is applied between the first electrode layer 221C and the second electrode layer 223C, the electric field is generated at the piezoelectric body layer 222C in the Z-axis direction. According to the electric field, the piezoelectric body layer 222C is extended or contracted in the Y-axis direction and the resonating arm 28C is flexurally vibrated in the Z-axis direction.

The same as above, the piezoelectric body element 23C is constituted such that a first electrode layer 231C, a piezoelectric body layer (piezoelectric thin film) 232C, and a second electrode layer 233C are laminated in this order on the resonating arm 29C. The piezoelectric body element 24C is constituted such that a first electrode layer 241C, a piezoelectric body layer (piezoelectric sheet film) 242C, and a second electrode layer 243C are laminated in this order on the resonating arm 30C.

As shown in FIG. 10, a plurality of fine holes 2331C that penetrates the second electrode layer 233C in the thickness direction is formed. As shown in FIG. 13, a plurality of fine holes 2311C that penetrates the first electrode layer 231C in the thickness direction is formed. Such a plurality of holes is formed at the first electrode layer 231C and the second electrode layer 233C so that the vibration characteristic of the resonating arm 29C is adjusted.

Also, as shown in FIG. 10, a plurality of fine holes 2431C that penetrates the second electrode layer 243C in the thickness direction is formed. As shown in FIG. 13, a plurality of fine holes 2411C that penetrates the first electrode layer 241C in the thickness direction is formed. Such a plurality of holes is formed at the first electrode layer 241C and the second electrode layer 243C so that the vibration characteristic of the resonating arm 30C is adjusted.

In the piezoelectric body element 23C, when a voltage is applied between the first electrode layer 231C and the second electrode layer 233C, the piezoelectric body layer 232C is extended or contracted in the Y-axis direction and the resonating arm 29C is flexurally vibrated in the Z-axis direction. When a voltage is applied between the first electrode layer 241C and the second electrode layer 243C, the piezoelectric body layer 242C is extended or contracted in the Y-axis direction and the resonating arm 30C is flexurally vibrated in the Z-axis direction.

As shown in FIGS. 10, 12, and 13, the above described first electrode layers 221C and 231C and the second electrode layer 243C are electrically connected to the connection electrode 41C arranged on the lower surface of the base portion 27C. The first electrode layer 241C and the second electrode layers 223C and 233C are electrically connected to the connection electrode 42C arranged on the lower surface of the base portion 27C. Thus, the first electrode layer 241C is electrically connected to the connection electrode 41C through the conductive portion (conductive post) 251 shown in FIG. 12. Also, the first electrode layers 221C and 231C is electrically connected to the connection electrode 42C through the conductive portion (conductive post) 252 shown in FIG. 12.

The first electrode layers 221C, 231C, and 241C, the second electrode layers 223C, 233C, and 243C, the connection electrodes 41C and 42C; and the conductive portions 251 and 252 are formed by a metal material that is excellent in conductivity such as aluminum, aluminum alloy, silver, silver alloy, chromium, chromium alloy, gold, or gold chromium laminated film, respectively.

As the forming method of these electrodes, the physical film forming method such as the sputtering method and the vacuum vapor deposition method, the chemical vapor deposition method such as CVD, and various coating methods such as an ink jet method can be used. When the electrodes are formed, it is preferable that a photolithography method is used.

As the constituent material (the piezoelectric body) of the piezoelectric body layers 222C, 232C, and 242C, for example, a crystal, lithium tantalite, lithium niobate, lithium borate, barium titanate, or the like are used.

As the forming method of these piezoelectric body layers, the physical film forming method such as the sputtering method and the vacuum vapor deposition method, the chemical vapor deposition method such as CVD, and various coating methods such as an ink jet method can be used.

In the resonator body 2C as described above, when a voltage is applied between the connection electrode 41C and the connection electrode 42C, the first electrode layers 221C and 231C and the second electrode layer 243C; and the first electrode layer 241C and the second electrode layers 223C and 233C have reverse polarities so that the voltage of the Z-axis direction is applied to the piezoelectric body layers 222C, 232C, and 242C. Thus, each of the resonating arms 28C, 29C, and 30C can be flexurally vibrated with a constant frequency (a resonance frequency) due to a reverse piezoelectric effect of the piezoelectric body.

As shown in FIG. 14, the resonating arms 28C and 29C are flexurally vibrated in the same direction to each other and the resonating arm 30C is flexurally vibrated in the direction opposite to the resonating arms 28C and 29C. Thus, the loss of the vibration can be prevented and three resonating arms 28C, 29C, and 30C can be flexurally vibrated in the Z-axis direction.

When the resonating arms 28C, 29C, and 30C are flexurally vibrated, a voltage with a constant frequency is generated between the connection electrodes 41C and 42C by the piezoelectric effect of the piezoelectric body. The resonator body 2C can generate the electrical signal that is vibrated in the resonance frequency using these characteristics.

In the embodiment, description was given in a case where the polarization direction or the direction of the crystal axis of the piezoelectric body of the piezoelectric body layers 222C, 232C, and 242C is the same direction to each other, however, the invention is not limited to the description and the voltage may be applied such that for example, the polarization direction or the direction of the crystal axis of the piezoelectric body layer 242C may be a reverse direction to the piezoelectric body layers 222C and 232C and the first electrode layers 221C, 231C, and 241C among themselves (the second electrode layers 223C, 233C, and 243C among themselves) may be the same polarization.

The adjustment of the vibration characteristic of the resonating arm 28C will be described. The adjustment of the vibration characteristic of the resonating arms 29C and 30C is the same as that of the resonating arm 28C so that the description thereof is omitted.

As described above, in the piezoelectric body element 22C, a plurality of fine holes 2211C that penetrates the first electrode layer 221C in the thickness direction is formed. A plurality of fine holes 2231C that penetrates the second electrode layer 223C in the thickness direction is formed.

Specifically, a plurality of fine holes 2211C that penetrates the first electrode layer 221C in the thickness direction is partially formed. A plurality of fine holes 2231C that penetrates the second electrode layer 223C in the thickness direction is partially formed.

Thus, even though the length L2 of the piezoelectric body element 22C in the Y-axis direction is long on the resonating arm 28C, density of an electric field that contributes to the unnecessary vibration mode is small, out of electric fields (electric fields that is applied to the piezoelectric body element 222C) that are generated between the first electrode layers 221C and the second electrode layer 223C so that the vibration characteristic of the resonating arm 28C can be adjusted.

Accordingly, the resonator body 20 can mitigate the unnecessary vibration mode and can be effectively vibrated.

A plurality of holes 2211C and 2231C is unevenly distributed (partially formed) respectively at halfway between the first electrode layer 221C or the second electrode layer 223C in the extension direction of the resonating arm 28C.

Accordingly, the ratio of the CI value of the harmonic wave (the higher order vibration mode) and a CI value of the fundamental wave is changed and then the vibration characteristic of the resonating arm 28C can be adjusted as the same as the resonating arm 28 of the above described embodiment.

A plurality of holes 2211C and 2231C is unevenly distributed (partially formed) respectively at the portion that corresponds to the center portion of the first electrode layer 221C or the second electrode layer 223C in the extension direction (the Y-axis direction) of the resonating arm 28C.

The excitation of the higher order vibration mode of the resonating arm 28C is widely suppressed so that the CI value of the higher order vibration mode of the resonator body 2C can be increased even though the length L2 of the piezoelectric body element 22C in the Y-axis direction is long. In other words, the CI value of the fundamental wave can be decreased and the CI value of the harmonic wave is increased so that the ratio of the CI values (the CI value of the harmonic wave/the CI value of the fundamental wave) can be increased as the same as the resonating arm 28 of the above-described embodiment.

When the length of the resonating arm 28C in the extension direction (the Y-axis direction) is L1 and the length of the piezoelectric body element 22C in the same direction on the resonating arm 28C is L2, the relation of 0.5<L2/L1<1 is satisfied. Accordingly, the CI value of the fundamental wave can be decreased and the excitation of the resonating arm 28C can be effectively performed as the same as that of the resonating arm 28 of the above-described embodiment. Specifically, from such a view point, the lengths L1 and L2 preferably satisfy the relation of 0.6<L2/L1<0.9 and further preferably satisfy the relation of 0.7<L2/L1<0.8 as the same as the resonating arm 28 of the above-described embodiment.

The ratio (the ratio of the hole presence) of the area in which the holes 2211C of the first electrode layer 221C take a share per a unit area and the ratio (the ratio of the hole presence) of the area in which the holes 2231C of the second electrode layer 223C take a share per a unit area are gradually decreased toward the front end side and the base end side from the center portion of the resonating arm 28C in the extension direction (the Y-axis direction) respectively. Accordingly, the excitation of the resonating arm 28C is smoothly and effectively performed and the CI value of the harmonic wave is increased so that the ratio of the CI values (the CI value of harmonic wave/the CI value of fundamental wave) can be increased the same as that of the resonating arm 28 of the above-described embodiment.

In the embodiment, the above described plurality of holes is formed on both of the first electrode layer 221C and the second electrode layer 223C, so that the number or area of a plurality of holes per one electrode layer can be decreased compared to the case where a plurality of holes is formed on only either one of the first electrode layer 221C or the second electrode layer 223C. Thus, the decrease of the mechanical strength of the first electrode layer 221C and the second electrode layer 223C can be prevented and the adjustment of the vibration characteristic of the resonating arm 28C can be performed. The holes 2211C and the holes 2231C are not overlapped as much as possible as seen in the plan view so that the effect becomes more remarkable.

Since the first electrode layer 221C and the second electrode layer 223C are relatively thin respectively, the formation of a plurality of holes 2211C and 2231C can be performed relatively simply and with high precision. Even though a plurality of the holes 2211C is arranged at the first electrode layer 221C, a step which is generated by a presence or an absence of the holes 2211C at the first electrode layer 221C is extremely small so that negative influence is not exerted on the formation of the piezoelectric body layer 222C. Also, since the second electrode layer 223C is formed after the formation of the first electrode layer 221C and the piezoelectric body layer 222C, the negative influence is not exerted on the formation of the first electrode layer 221C and the piezoelectric body layer 222C even though a plurality of the holes 2231C is arranged at the second electrode layer 223C.

In the embodiment, a plurality of holes such as a plurality of the holes 2211C and 2231C is not formed at the piezoelectric body layer 222C. In other words, the piezoelectric body layer 222C is constituted such that the inner side of the contour thereof is not patterned but densely layered. Thus, the surface of the piezoelectric body layer 222C can be platen. As a result, the second electrode layer 223C can be evenly formed. The distance between the first electrode layer 221C and the second electrode layer 223C can be uniformly formed.

Even though a plurality of holes such as a plurality of the holes 2211C and 2231C is formed at the piezoelectric body layer 222C, the adjustment of the vibration characteristic of the resonating arm 28C can be performed.

Also, each of the holes 2211C and 2231C is a slit shape seen from the plan view. The shape of the holes 2211C and 2231C seen from the plan view can be easily formed with a highly precise dimension and position. The bad influence that is exerted on the piezoelectric body element 22C can also be small. Specifically, the width, the distance (the pitch), the length, or the like of each of the holes 2211C and 2231C are changed so that the vibration characteristic of the resonating arm 28C can be adjusted. Thus, the resonating arm 28C can be relatively simply adjusted to the desired vibration characteristic.

Each of the holes 2211C and 2231C having the slit shape is extended to the width direction (the X-axis direction) that is orthogonal to the extension direction (the Y-axis direction) of the resonating arm 28C. Thus, the formation of a plurality of the holes 2211C and 2231C can prevent negatively influencing the vibration characteristic of the resonating arm 28C. Thus, the resonating arm 28C can be relatively simply adjusted to the desired vibration characteristic. Each of the holes 2211C and 2231C having the slit shape may also be formed so as to extend in the Y-axis direction.

In the embodiment, a plurality of the holes 2211C and 2231C is formed so as to have the same length and width to each other. Thus, the distance among the holes 2211C and the distance among the holes 2231C are changed according to the position in the Y-axis direction so that the ratio of the hole presence is realized as described above.

Also, a plurality of the holes 2211C and 2231C may also be formed so as to have a different length and width to each other. In this case, even though the distance among the holes 2211C and the distance among the holes 2231C are constant, the length and the width of each of the holes 2211C and 2231C are changed according to the position in the Y-axis direction so that the ratio of the hole presence can be realized as described above.

The width of the plurality of holes 2211C and 2231C having the slit shape is preferably 0.01 to 100 μm and more preferably 0.1 to 10 μm. Thus, the formation of a plurality of the holes 2211C and 2231C is relatively easily performed and the resonating arm 28C can be adjusted to a desired vibration characteristic.

According to the above described fourth embodiment, effect of the same as that of the first embodiment can be present.

### Fifth Embodiment

Next, a fifth embodiment of the resonator device according to the invention will be described.

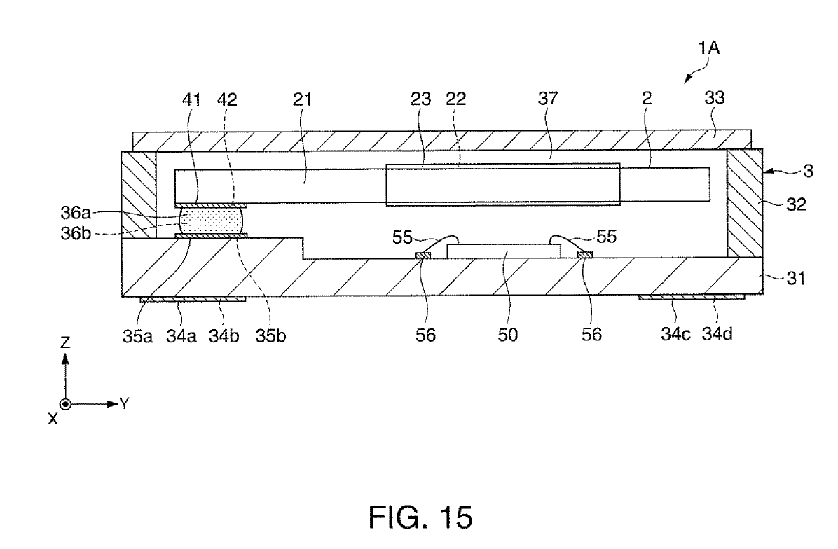

FIG. 15 is a cross section view illustrating the resonator device of a fifth embodiment according to the invention.

Hereinafter, description will be given regarding the resonator device of the fifth embodiment focused on differences from the above described embodiments and the same articles thereof will not be described repeatedly.

As shown in FIG. 15, a resonator device 1A of the fifth embodiment has a driving circuit portion (a circuit portion) 50 that drives the resonator body 2, a circuit connection terminal 56 and metal wires (bonding wire) 55 that electrically connect between the driving circuit portion 50 and the circuit connection terminal 56 within case 3, additionally to the constitution of the resonator device 1 that includes the resonator body 2 in the first embodiment. In other words, the resonator device 1A has a function as a so-called oscillator. The resonator body 2 may be any one of vibration bodies 2A, 2B, and 2C.

In this case, a base substrate 31 of the package 3 having the resonator device 1A has a step portion of a step in the surface of an inner space 37 and a pair of mount electrodes 35a and 35b is formed on the upper surface of the step portion of the upper side thereof as described above in FIG. 1. Meanwhile, the driving circuit portion 50 is loaded on the step surface of the lower side of the base substrate 31 and a plurality of circuit connection terminals 56 is arranged so as to electrically connect through the driving circuit portion 50 and the metal wire 55. The driving circuit portion 50 is an IC chip having a semiconductor circuit element including an oscillation circuit that oscillates the resonator body 2, a temperature compensating circuit or the like, and attached and fixed at the step surface of the package 3 by the brazing filler material.

Four outer terminals 34a, 34b, 34c, and 34d are arranged on the lower surface of the base substrate 31. The mount electrodes 35a and 35b, the circuit connection terminal 56 and the outer terminals 34a to 34d that are arranged in the package 3 are connected in corresponding terminals to each other by a wiring within the layer such as a drawing wiring or through hole. If necessary, a write-in terminal that is to perform a rewrite (adjustment) of a characteristic inspection of the driving circuit portion 50 or all types of information (for example, the temperature compensating information of the resonator device) may be formed on the lower surface of the base substrate 31.

The resonator device 1A can function as the oscillator having an excellent oscillation characteristic as the resonator body 2 which includes a plurality of holes and an unnecessary vibration mode is mitigated so as to be effectively driven.

### Electronic Device

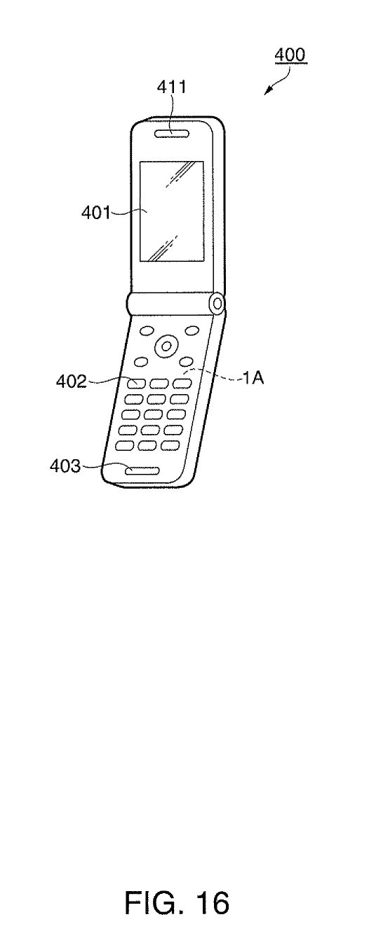

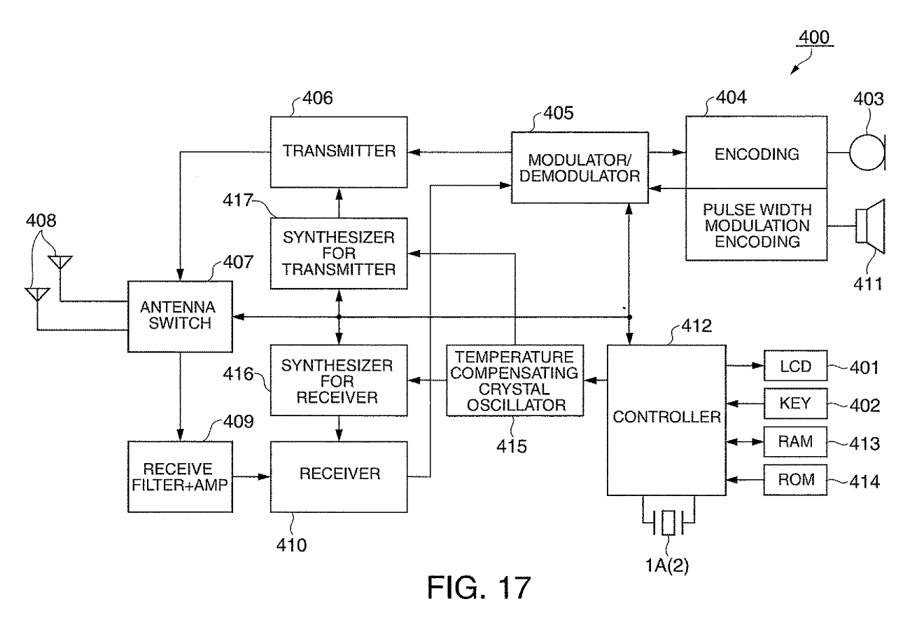

The resonator device 1A having any one of the vibration bodies 2, 2A, 2B, and 2C of each of the embodiments described above can be applied to all types of electronic devices and these electronic devices have high reliability. FIGS. 16 and 17 illustrate a cellular phone as an example of the electronic devices according to the invention. FIG. 16 is a perspective view schematically illustrating the outer appearance of the cellular phone, and FIG. 17 is a circuit block illustrating a circuit constitution of the cellular phone. The cellular phone 400 is illustrated as an example that uses the resonator device 1A (see FIG. 15) having the resonator body 2, and regarding the constitution and the function of the resonator body 2, similar reference numbers are used and the description thereof are omitted.

As shown in FIG. 16, the cellular phone 400 includes a LCD (Liquid Crystal Display) 401 that is a display portion, a key 402 that is an input portion such as numbers, a microphone 403, a speaker 411, and the like. As shown in FIG. 16, in a case where transmittance is performed in the cellular phone 400, when the user inputs a voice of themselves to the microphone 403, a signal is transmitted from an antenna 408 via a pulse width modulation-encoding block 404 and a modulator/demodulator block 405 and through a transmitter 406 and an antenna switch 407.

Meanwhile, a signal that is received from a telephone of other people is received from the antenna 408 and input to the modulator/demodulator block 405 from a receiver 410 via the antenna switch 407 and a receiving filter 409. Thus, the modulated or demodulated signal is output to a speaker 411 as a voice via the pulse width modulation-encoding block 404. A controller 412 is arranged so as to control the antenna switch 407, the modulator/demodulator 405, or the like.

The controller 412 is required to be high precise so as to also control the LCD 401 that is other than the above-described display portion, a key 402 that is the input portion of the numbers or the like, a RAM 413 or a ROM 414. There is a need for the cellular phone 400 to be compact so that the above described resonator body 2 is used to meet the need. The cellular phone 400 also includes a temperature compensating crystal oscillator 415, a synthesizer 416 for the receiver, a synthesizer 417 for the transmitter, or the like as other constitution blocks, however, the description thereof is omitted.

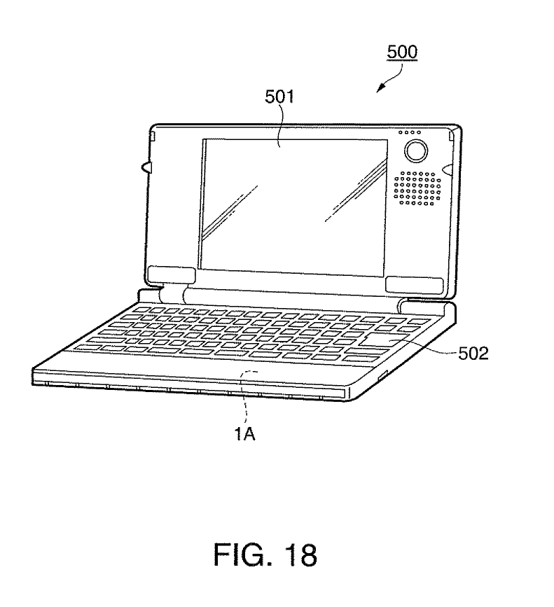

As the electronic device including the resonator device 1A according to the invention, there is a personal computer (a mobile personal computer) 500 as shown in FIG. 18. The personal computer 500 includes a display portion 501, an input key portion 502 or the like, and uses the above described resonator device 1 as the reference clock of the electric control.

In the resonator device 1A that is used in the cellular phone 400 or the personal computer 500, if the resonator body 2 is used, the length of the excitation electrode groups 22 and 23 in the first direction (the extension direction of the resonating arm) is long on the resonating arms 28 and 29; and the density of an electric field that is contributed to the unnecessary vibration mode of the electric fields (the electric field that is applied to the resonating arm) that is generated between a pair of the excitation electrodes is small so that the excitation characteristic of the resonating arms 28 and 29 can be enhanced. Thus, the resonator device 1 can mitigate the unnecessary vibration mode and can be effectively driven. The cellular phone 400 and the personal computer 500 that include the resonator device 1 can maintain high reliability. In the resonator device 1, even if the vibration bodies 2A, 2B, and 2C are used, the cellular phone 400 and the personal computer 500 can maintain the same effect as the above description.

The resonator device 1A of each of the above described embodiments can also be applied to various electronic devices other than the cellular phone 400 and the personal computer 500, and the obtained electronic device has a high reliability.

The electronic devices includes for example, personal computers (the mobile personal computers), cellular phones, digital-still cameras, ink jet ejection apparatuses (for example, ink jet printers), laptop personal computers, televisions, vides cameras, video tape recorders, car navigation apparatuses, pagers, electronic pocket books (including ones with communication capabilities), electronic dictionaries, calculators, electronic gaming machines, word processors, work stations, television phones, surveillance TV monitors, electronic binoculars, POS terminals, medical devices (for example, electronic thermometers, sphygmomanometers, blood glucose meters, electrocardiogram measuring systems, ultrasonic diagnosis devices, and electronic endoscopes), fishfinders, various measurement instruments, various indicators (for example, indicators used in vehicles, airplanes, and ships), flight simulators, and the like.

While the resonator device 1A according to the invention and the electronic device has been described based on the embodiment illustrated in the drawings, the invention is not limited to the embodiments; the configuration of the respective portions can be replaced with any configurations having the same function. Moreover, other arbitrary constituent elements may be added to the invention. The invention may combine two or more arbitrary constituents (characteristics) of each of the embodiments.

For example, in the above described embodiments, the description has been given in a case where the vibration bodies 2, 2A, 2B, and 2C have two or three resonating arms, however, the number of resonating arms may be one, or four or more.

Furthermore, in the above described fourth embodiment, the description has been given in a case where a plurality of fine holes is formed at both of the first electrode layers 221C, 231C, and 241C and the second electrode layers 223C, 233C, and 243C of the piezoelectric body elements 22C, 23C, and 24C, however, even though a plurality of fine holes is formed at only one electrode layer in any one of the first electrode layers 221C, 231C, and 241C or the second electrode layers 223C, 233C, and 243C, the vibration characteristic of the resonating arms 28C, 29C, and 30C can be adjusted.

Also, the resonator device 1A according to the invention may be applied to a gyro sensor or the like, in addition to piezoelectric oscillators such as a crystal oscillator (SPXO), a voltage-controlled crystal oscillator (VCXO), a temperature-compensated crystal oscillator (TCXO), or an oven-controlled crystal oscillator (OCXO).

The entire disclosure of Japanese Patent Application Nos: 2010-062060, filed Mar. 18, 2010 and 2010-292042, filed Dec. 28, 2010 are expressly incorporated by reference herein.

What is claimed is:

1. A resonator body comprising:
a base portion,
a plurality of resonating arms that is extended from the base portion in a first direction and arranged in parallel to a second direction that is orthogonal to the first direction, and
a pair of excitation electrodes that is arranged on each of the resonating arms and excites the resonating arms by applying an electric current,
wherein a plurality of holes that partially penetrates the excitation electrode of at least one side of a pair of excitation electrodes in a thickness direction is formed.

2. The resonator body according to claim 1, wherein a plurality of holes is unevenly distributed and formed at least one of the excitation electrodes in the first direction.

3. The resonator body according to claim 2, wherein a plurality of holes is unevenly distributed and formed at the center portion of the resonating arm of the excitation electrode in the first direction.

4. The resonator body according to claim 3, wherein a ratio of the area in which the holes of the excitation electrode take a share per a unit area is gradually decreased toward a front end side from the center portion of the resonating arm in the first direction.

5. The resonator body according to claim 3, wherein a ratio of the area in which the holes of the excitation electrode take a share per a unit area is gradually decreased toward a base end side from a center portion of the resonating arm in the first direction.

6. The resonator body according to claim 1, wherein when a length of the resonating arm in the first direction is L1 and a length of the excitation electrode in the same direction on the resonating arm is L2, a relation of 0.5<L2/L1<1 satisfied.

7. The resonator body according to claim 1, wherein each hole is a circular shape seen in a plan view.

8. The resonator body according to claim 7, wherein an average diameter of the plurality of holes is 0.01 to 100 μm.

9. The resonator body according to claim 1, wherein each of the holes is a slit shape seen in a plan view.

10. The resonator body according to claim 9, wherein each hole having the slit shape is extended to the second direction.

11. The resonator body according to claim 9, wherein a width of the holes having the slit shape is 0.01 to 100 μm.

12. A resonator body comprising:
a base portion,
a plurality of resonating arms that is extended from the base portion to a first direction and arranged in parallel to a second direction that is orthogonal to the first direction, and
a piezoelectric body element that is arranged on each of the resonating arms and expanding and contracting so as to vibrate the resonating arms by applying an electric current,
wherein the piezoelectric body element has a first electrode layer and a second electrode layer and piezoelectric body layers that are positioned between the first electrode layer and the second electrode layer,
wherein a plurality of holes that partially penetrates at least one layer of the first electrode layer, the piezoelectric body layer, and the second electrode layer in a thickness direction is formed.

13. The resonator body according to claim 12, wherein the resonating arms are three or more, and adjacent two resonating arms are flexurally vibrated by expanding and contracting of the piezoelectric body element in opposite directions to each other in a third direction that is orthogonal to the first direction and the second direction.

14. A resonator device comprising:
the resonator body according to claim 1, and
a package that accommodates the resonator body.

15. A resonator device comprising:
the resonator body according to claim 1,
a circuit portion that is electrically connected to the resonator body, and
a package that accommodates the resonator body and the circuit portion.

16. An electronic device comprising:
the resonator device according to claim 15.
